(19) United States
(12) Patent Application Publication
(10) Pub. No.: US 2004/0253751 A1
(43) Pub. Date: Dec. 16, 2004

(54) Photothermal ultra-shallow junction monitoring system with UV pump

(76) Inventors: Alex Salnik, Castro Valley, CA (US); Lena Nicolaides, Castro Valley, CA (US); Jon Opsal, Livermore, CA (US)

Correspondence Address: STALLMAN & POLLOCK LLP, SUITE 2200, 353 SACRAMENTO STREET, SAN FRANCISCO, CA, 94111, US

(21) Appl. No.: 10/859,846

(22) Filed: Jun. 3, 2004

Related U.S. Application Data
(60) Provisional application No. 60/478,883, filed on Jun. 16, 2003.

(51) Int. Cl. H01L 21/66; G01R 31/26; G01J 1/42; G01J 3/45; G01B 9/02

(52) U.S. Cl. 438/16; 356/455; 356/432; 250/372

(57) ABSTRACT

A modulated reflectance measurement system includes two lasers for generating a probe beam and an intensity modulated pump beam. The probe beam is in the visible spectrum and the pump beam is in the ultra-violet spectrum. The pump and probe beams are joined into a collinear beam and focused by an objective lens onto a sample. Reflected energy returns through the objective and is redirected by a beam splitter to a detector. A lock-in amplifier converts the output of the detector to produce quadrature (Q) and in-phase (I) signals for analysis. A processor uses the Q and/or I signals to analyze the sample.

### PRIORITY CLAIM

The present application claims priority to U.S. Provisional Patent Application Serial No. 60/478,883, filed Jun. 16, 2003, the disclosure of which is incorporated herein by reference.

### TECHNICAL FIELD

The subject invention relates generally to optical methods for inspecting and analyzing semiconductor wafers and other samples. In particular, the subject invention relates to methods for characterization of ultra-shallow junctions within semiconductor wafers.

### BACKGROUND OF THE INVENTION

In the processing of a semiconductor wafer to form integrated circuits, charged atoms (ions) are directly introduced into the wafer in a process known as ion implantation. Ion implantation normally causes damage to the lattice of a semiconductor wafer, and to remove the damage, the wafer is normally annealed at an elevated temperature. The annealing process also activates implanted ions and changes the type of electrical conductivity of the uppermost layer of a semiconductor. After annealing, there is a very thin layer of usually highly doped semiconductor on top of undoped or slightly doped substrate. This layer is called an ultra-shallow junction (USJ).

There is a great need in the semiconductor industry for sensitive metrology equipment that can provide high resolution and noncontact evaluation of product Si wafers as they pass through the implantation and annealing fabrication stages. In recent years, a number of products have been developed for the nondestructive evaluation of semiconductor materials. One such product has been successfully marketed by assignee herein under the trademark Therma-Probe (TP). This system incorporates technology described in the following U.S. Pat. Nos.: 4,634,290; 4,636,088; 4,854,710; 5,074,669 and 5,978,074. These patents are incorporated in this document by reference.

In the basic device described in the patents just cited, an intensity modulated pump laser having a wavelength from the visible part of the spectrum is focused on the sample surface for periodically exciting the sample. In the case of a semiconductor, thermal and carrier plasma waves are generated close to the sample surface which spread out from the pump beam spot inside the sample.

The presence of the thermal and carrier plasma waves affects the reflectivity R at the surface of a semiconductor. Features and regions below the sample surface, such as an implanted region or ultra-shallow junction that alter the propagation of the thermal and carrier plasma waves will therefore change the optical reflective pattern at the surface. By monitoring the changes in R of the sample at the surface, information about characteristics below the surface, such as a degree of damage introduced during the ion implantation process (implantation dose) and/or characteristic depth of the doped region below the sample surface (ultra-shallow junction depth) can be investigated.

In the basic device, a second laser having a visible wavelength different from that of the pump laser is provided for generating a probe beam of radiation. This probe beam is focused collinearly with the pump beam and reflects off the sample surface. A photodetector is provided for monitoring the power of reflected probe beam. This photodetector generates an output signal that is proportional to the reflected power of the probe beam and is therefore indicative of the varying optical reflectivity of the sample surface. A lock-in detector is used to measure both the in-phase (I) and quadrature (Q) components of the signal. The two channels of the output signal, namely the amplitude A²=I²+Q² and phase Θ=tan⁻¹(I/Q) are conventionally referred to as the Photomodulated Reflectivity (PMR) or Thermal Wave (TW) signal amplitude and phase, respectively.

Dynamics of the thermal and carrier plasma related components of the total TW signal in a semiconductor is given by the following general equation:

$$\frac{Δ R}{R} = \frac{1}{R} ( \frac{\partial R}{\partial T} Δ {T}_{0} + \frac{\partial R}{\partial N} Δ {N}_{0} ) \qquad ( 1 )$$

where ΔT₀ and ΔN₀ are the temperature and the carrier plasma density at the surface of a semiconductor. R is the reflectance, ∂R/∂T is the temperature reflectance coefficient and ∂R/∂N is the carrier reflectance coefficient. For crystalline silicon, ∂R/∂T is positive in the visible and near-UV parts of the spectrum while ∂R/∂N remains negative throughout the entire spectrum region of interest. This difference in signs results in a destructive interference between the thermal and carrier plasma wave causing a decrease in the total PMR signal. The magnitude of this effect depends on the properties of a semiconductor sample and on the parameters of the photothermal system, especially on the pump and probe beam wavelengths.

In the assignee's early commercial embodiments of the TP system, both the pump and probe beams were generated by gas discharge lasers. Specifically, an argon-ion laser emitting a wavelength of 488 nm was used as a pump source. A helium-neon laser operating at 633 nm was used as a source of the probe beam. More recently, the assignee has used solid state laser diodes that are generally more reliable and have a longer lifetime than the gas discharge lasers. In the current commercial embodiment, the pump laser operates at 780 nm while the probe laser operates at 670 nm.

This combination of the pump and probe beam wavelengths selected by the assignee in its current TP system has been driven by the availability of commercial diode lasers and is intended to cover a relatively broad range of samples and applications, including ion-implanted Si wafers and Si wafers with USJ. However, as it will be shown here, in the case of TP applications for characterization of ultra-shallow junctions the current set of pump and probe beam wavelength has several disadvantages.

For example, one of the main disadvantages is the oscillating TW response from the USJ samples with different junction depth. This is illustrated schematically in FIG. 1. Experimentally measured TW responses (squares) from USJ samples with varying junction depth follow a sinusoidal dependence. A solid line represents the theoretical simulations. System sensitivity to junction depth is defined by the rising or falling “wings” of this dependence. Correspondingly, at the extreme points 10 and 11 of this curve (i.e. around 600 Å and 1000 Å junction depth) the TW signal has a very low (zero) sensitivity to variations in junction depth. Thus, it would be desirable to have a photothermal system that has flatter TW response as a function of junction depth without the extreme points and, therefore, much uniform sensitivity.

Another disadvantage of the photothermal system with current set of pump and probe beam wavelengths is also coming from the sine-like TW signal dependence on junction depth. It is illustrated in FIG. 2. Here, squares and circles represent the experimental TW amplitude (right scale) and phase (left scale) values, respectively. Experimental points 12 and 13 are on the “wings” of the sinusoidal dependence and therefore should exhibit a good sensitivity to junction depth. However, their corresponding TW amplitude and phase values are the same. In FIG. 2 this fact is illustrated by dotted arrows. In this case it is very difficult to establish a correlation between TW amplitude and/or phase and the junction depth leading to an uncertainty in determining the depth of ultra-shallow junction. Thus, it would be desirable to have a photothermal system free of such uncertainties.

One of the most important parameters of the photothermal system defining its overall performance is repeatability. There is a strong correlation between system's repeatability and the signal-to-noise (S/N) ratio. One way to improve S/N is to increase the signal strength. Therefore, it is desirable to have a photothermal system with stronger signal and better repeatability.

Yet another disadvantage of the current commercial embodiment is its inability to perform measurements of several physical parameters characterizing the ultra-shallow junction. Examples of material properties of interest include surface concentration, carrier mobility, junction depth, carrier lifetime and defects that cause leakage current at the ultra-shallow junction. The current photothermal system can be calibrated to measure only one of these parameters (usually its junction depth). It would be desirable to have a photothermal system capable of measuring two or more physical parameters of interest simultaneously.

### SUMMARY

The present invention provides a modulated reflectance measurement system for characterizing ultra-shallow junctions. The measurement system includes a pump laser producing a near ultra-violet to ultra-violet pump beam. A modulator is used to cause the pump beam to be intensity modulated. The measurement system also includes a probe laser that produces a probe beam, typically in the visible spectrum. The probe beam is typically continuous (i.e., not intensity modulated).

The output of the probe laser and the output of the pump laser are joined into a collinear beam. Typically, this is accomplished using a laser diode power combiner connected to the pump and probe lasers using optical fibers. Other fiber and non-fiber based methods can also be used to perform the beam combination. Once combined, an optical fiber transports the now collinear probe and pump beams from the laser diode power combiner to a lens or other optical device for collimation. Once collimated, the collinear beam is focused on a sample by an objective lens.

A reflected portion of the collinear probe and pump beams is redirected by a beam splitter towards a detector. The detector measures the energy reflected by the sample and forwards a corresponding signal to a filter. The filter typically includes a lock-in amplifier that uses the output of the detector, along with the output of the modulator to produce quadrature (Q) and in-phase (I) signals for analysis. A processor typically converts the Q and I signals to amplitude and/or phase values to analyze the sample. In other cases, the Q and I signals are used directly.

By using a UV pump beam, the ability of the measurement system to characterize ultra-shallow junctions is dramatically improved in comparison with prior art measurement systems.

### BRIEF DESCRIPTION OF THE DRAWINGS

FIG. 1 is a plot showing the photothermal response of a prior art modulated reflectance measurement system as a function of junction depth.

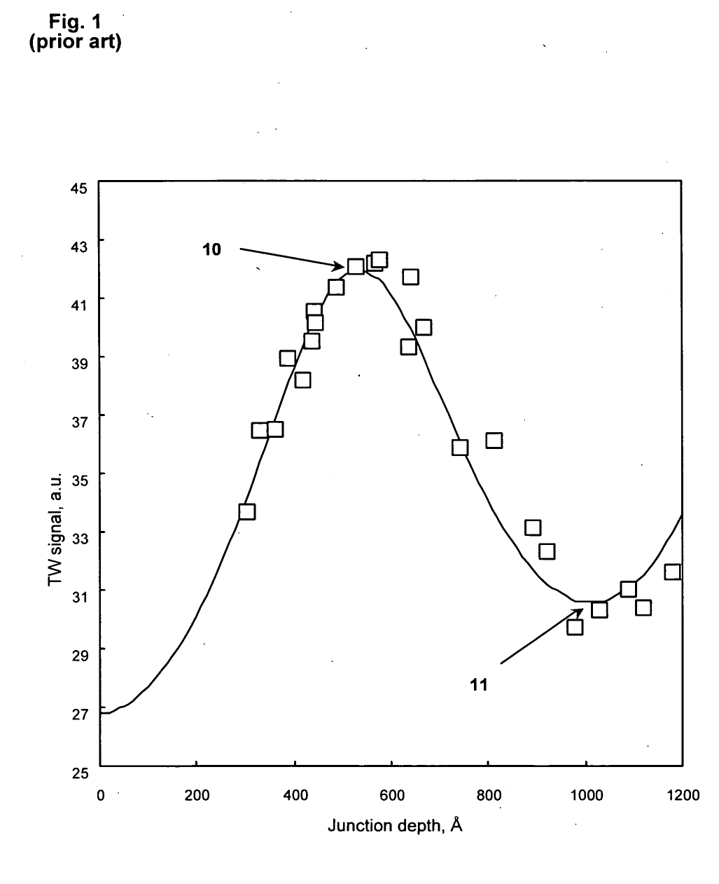

FIG. 2 is a plot showing phase and amplitude measurements obtained by a prior art modulated reflectance measurement system as a function of junction depth.

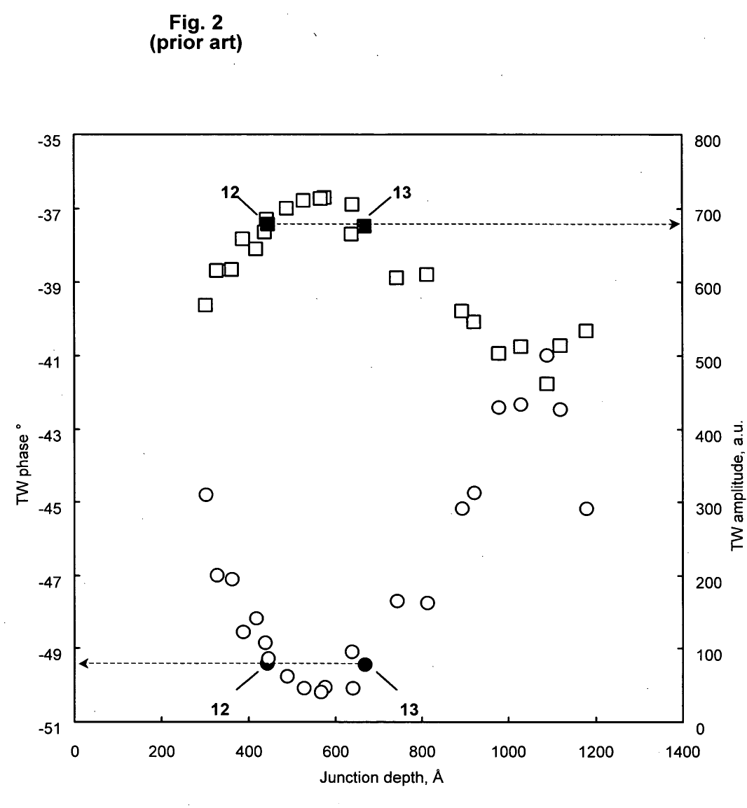

FIG. 3 is a block diagram of a modulated reflectance measurement system as provided by an embodiment of the present invention.

FIG. 4 is a combined plot comparing the photothermal response of the modulated reflectance measurement system of FIG. 3 with a prior art system.

FIG. 5 is a combined plot showing the photothermal response of the modulated reflectance measurement system of FIG. 3 along with its carrier plasma wave component and thermal component.

FIG. 6 is a combined plot comparing the photothermal response of the modulated reflectance measurement system of FIG. 3 with a prior art system where both responses are plotted as functions of junction depth.

FIG. 7 is a combined plot showing the photothermal response of the modulated reflectance measurement system of FIG. 3 along with its carrier plasma wave component and thermal component where all values are plotted as a function of junction depth.

FIG. 8 is a combined plot showing the gain in sensitivity to junction depth and gain in signal for the modulated reflectance measurement system of FIG. 3 compared to a prior art system.

FIG. 9 is a plot describing the phase sensitivity of the modulated reflectance measurement system of FIG. 3 as a function of junction depth.

FIG. 10 is a combined plot showing photothermal responses obtained using the modulated reflectance measurement system of FIG. 3 for three samples having different ratios of carrier mobility between a USJ layer and an underlying layer.

FIG. 11 shows the phase components of the measurements shown in FIG. 10.

FIG. 12 is a combined plot showing photothermal responses obtained using the modulated reflectance measurement system of FIG. 3 for three different pump beam wavelengths.

### DETAILED DESCRIPTION OF THE PREFERRED EMBODIMENTS

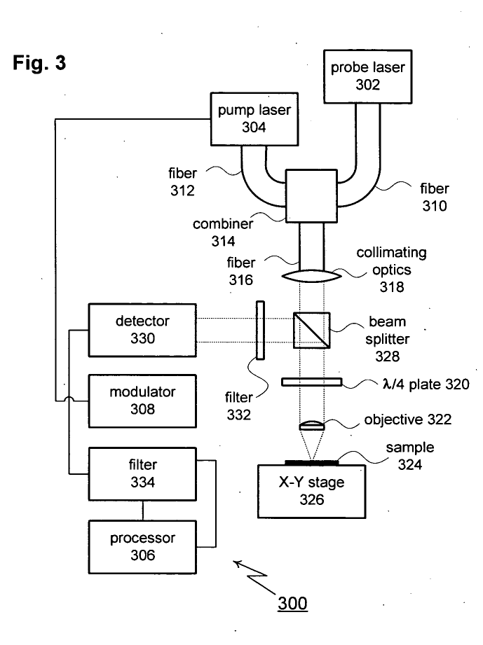

The present invention provides a modulated reflectance measurement system for characterization of ultra-shallow junctions. In FIG. 3, one possible implementation for the modulated reflectance measurement system is shown and generally designated 300. As shown, modulated reflectance measurement system 300 includes a probe laser 302 that creates an output (known as the probe beam) in the visible part of the spectrum (500 to 800 nm). In an alternate embodiment, the probe beam wavelength is tunable. System 300 also includes a pump laser 304 with an output (known as the pump beam) in the UV to near-UV spectral range (320 to 420 nm). Lasers 302, 304 are generally diode-based or diode-pumped semiconductor lasers. Lasers 302, 304 are controlled by a processor 306 and a modulator 308. Modulator 308 causes the pump beam output of laser 304 to be intensity modulated. Probe laser 302 produces an output that is typically non-modulated (i.e., constant intensity).

The probe beam output of probe laser 302 and pump beam output of pump laser 304 are collected by optical fibers 310 and 312, respectively. Fibers 310 and 312 direct the probe and pump beams to a combiner 314. Beam combiner 314 may be selected from a wide range of suitable types including part number FOBS-12P manufactured by OZ Optics. Once combined, the now collinear probe and pump beams are focused into fiber 316 and conveyed through collimating optics 318, quarter-wave plate 320 and objective 322 to sample 324. Sample 324 is positioned on an X-Y stage 326 allowing sample 324 to be moved in translation relative to the collinear beams.

After striking sample 324, a reflected portion of the collinear probe and pump beams is redirected by a beam splitter 328 towards a detector 330. A filter 332 removes the probe beam components of the energy received by detector 330. Detector 330 measures the energy reflected by sample 324 and forwards a corresponding signal to a filter 334. Filter 334 typically includes a lock-in amplifier that uses the output of detector 330, along with the output of modulator 308 to produce quadrature (Q) and in-phase (I) signals for analysis. Processor 306 typically converts the Q and I signals to amplitude and/or phase values to analyze the sample. In other cases, the Q and I signals are used directly.

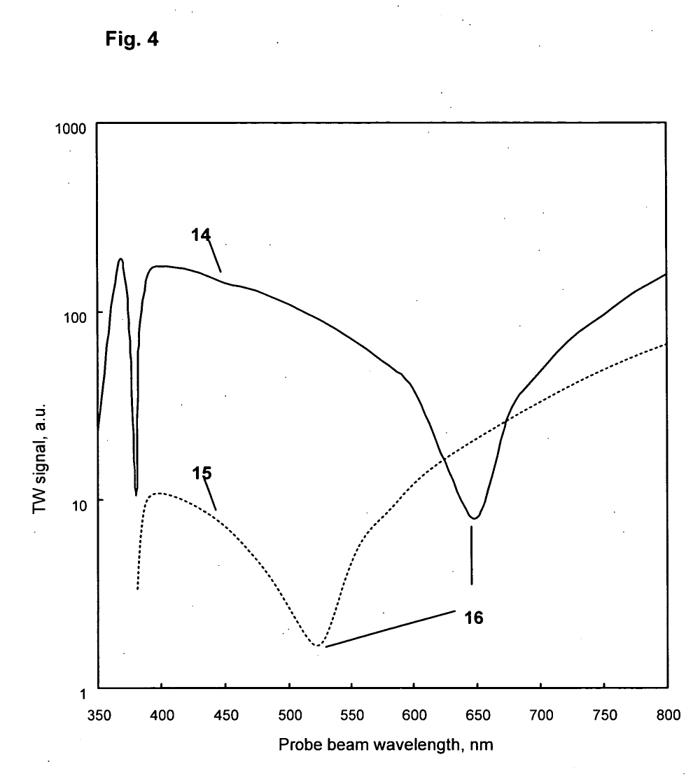

In FIG. 4 the TW signal response of system 300 is labeled 14. For this example, the pump beam is fixed at 405 nm. The probe beam varies over the range of 350 to 800 nm. FIG. 4 also shows the TW signal response of a prior art system (labeled 15). As can be appreciated, the TW response 14 (obtained with system 300) with pump beam wavelength of 405 nm is much stronger than that for the prior art system 15 with pump beam wavelength of 790 nm. Compared to the prior art system 15, near-UV pump beam of system 300 produces much stronger thermal wave component of the total TW signal resulting in shift of a characteristic plasma-thermal interference region 16 towards longer wavelengths.

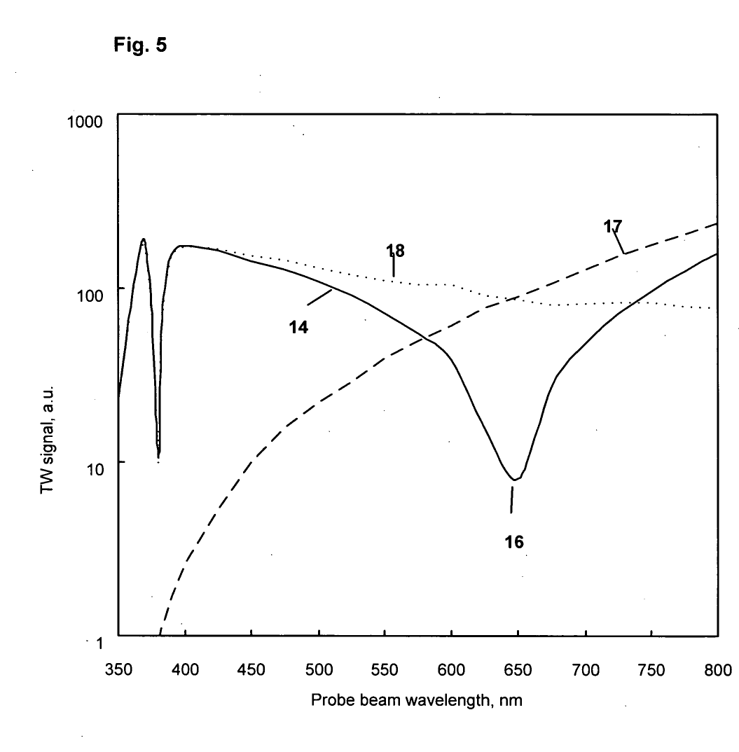

The origin of a deep negative peak 16 in TW dependence on probe wavelength is explained in FIG. 5. FIG. 5 shows the TW signal response of system 300 (labeled 14) along with its carrier plasma wave component (labeled 17) and thermal component (labeled 18). At longer probe beam wavelengths (700 nm and higher), the TW signal is dominated by the carrier plasma wave component 17. Thermal wave component 18 becomes dominant at shorter wavelengths (below 600 nm). As discussed above (Eq.(1)), the carrier plasma and thermal contributions have opposite signs in the visible part of spectrum. Negative peak 16 in FIG. 5 appears as a result of interference between the plasma and thermal waves in the 600-700 nm region.

Using near-UV pump wavelength results in significant increase in TW signal strength. Based on the availability of commercial diode lasers in this part of the spectrum and on the limitations imposed by UV optics, the optimal wavelength for the pump beam in system 300 is selected to be within the range of 320-420 nm. More preferably, the range of 390-410 nm is used with a particularly preferably implementation at 405 nm.

Probe beam wavelength for system 300 has been selected to be 675 nm, i.e., from the spectral region of the most intense thermal and plasma wave interference (FIG. 5). Despite the fact that the TW signal in this spectral region is lower due to the interference, it has still been found advantageous to use probe beam wavelength around 675 nm because of the TW phase sensitivity to junction depth and carrier mobility. A more detailed explanation will be provided below.

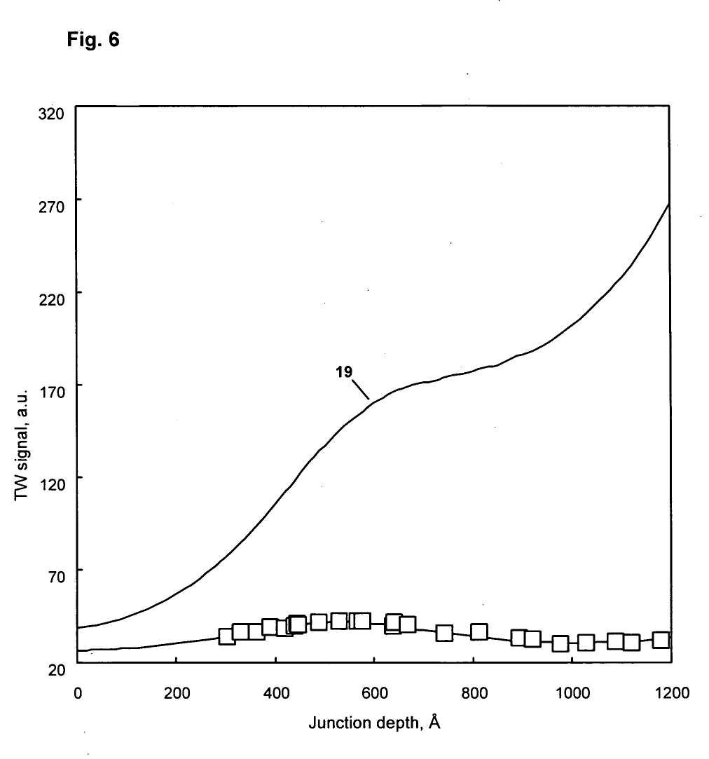

Photothermal response from system 300 has been examined for a typical USJ sample. A list of the optical, thermal, and electronic parameters used in calculations using a prior art system and system 300 is given in Table 1. The results of these calculations are presented in FIG. 6. As can be appreciated, the photothermal response 19 from system 300 is much stronger than that from a prior art system represented in the bottom of FIG. 6 by experimental points and theoretical fitting. Most importantly, the photothermal response 19 from system 300 is much flatter, has little cycling and, therefore is free from the main disadvantages of the prior art system mentioned above.

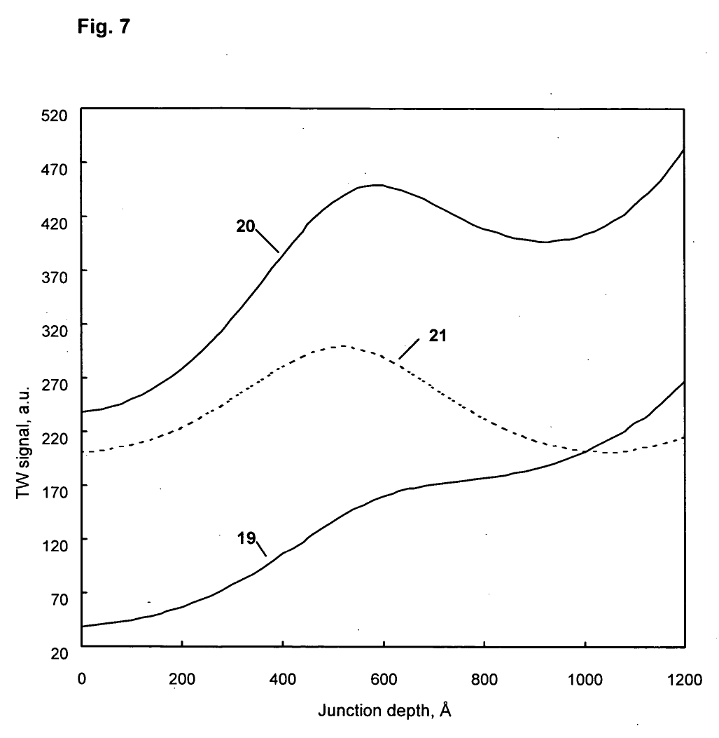

The origin of this flat behavior of the TW response as a function of junction depth is explained in FIG. 7. Cycling-free behavior of the total TW response 19 is due to the interference effect between the carrier plasma component 20 and the thermal component 21. In this spectral region of probe beam wavelengths, thermal and carrier plasma wave components are comparable in size and partially canceling each other. Note, that the oscillating carrier plasma component 20 has a rising average due to the contrast in carrier mobility between the USJ layer and substrate and due to a strong absorption of near-UV pump irradiation while thermal wave component 21 oscillates along a constant average. These two facts result in flattening of the TW response 19.

It can be shown that, despite somewhat approximate and simplified modeling described in this disclosure, there is always a probe beam wavelength at which carrier plasma and thermal component will interfere in the manner described above leading to a flatter TW response. This probe beam wavelength could be slightly different from ˜650 nm shown in FIG. 4 and FIG. 5.

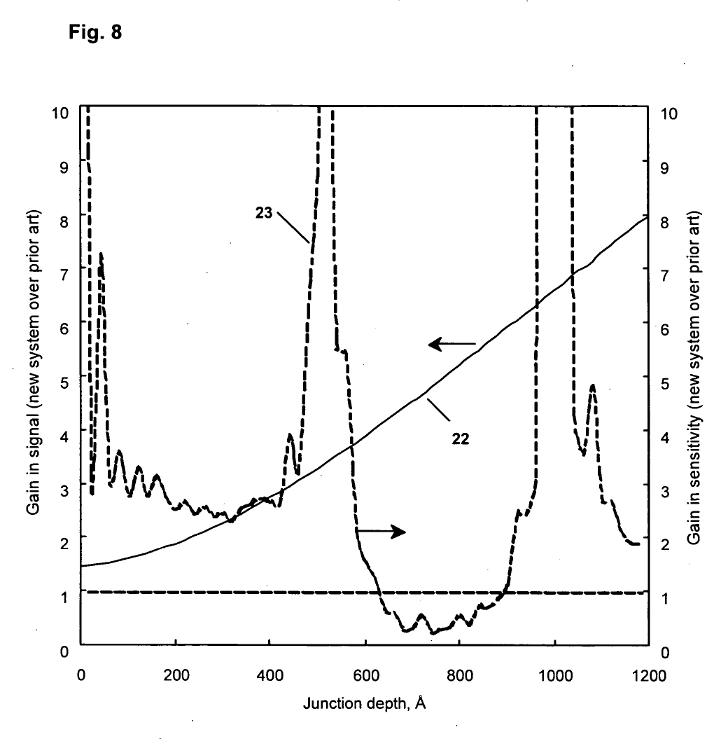

The graph of FIG. 8 shows two curves. The first curve, labeled 22 corresponds to the gain in signal strength obtained by system 300 when compared to a prior art system. Curve 22 is interpreted using the left scale. The second curve, labeled 23 corresponds to the sensitivity to junction depth obtained by system 300 when compared to a prior art system. Curve 23 is interpreted using the right scale. FIG. 8 clearly demonstrates the advantages of system 300 with respect to the prior art system. In the practically important region of junction depths (below 500 Å), system 300 exhibits an average 3× gain in signal strength and an average 3× gain in TW signal sensitivity to junction depth bringing a total factor of improvement in system performance to 9×.

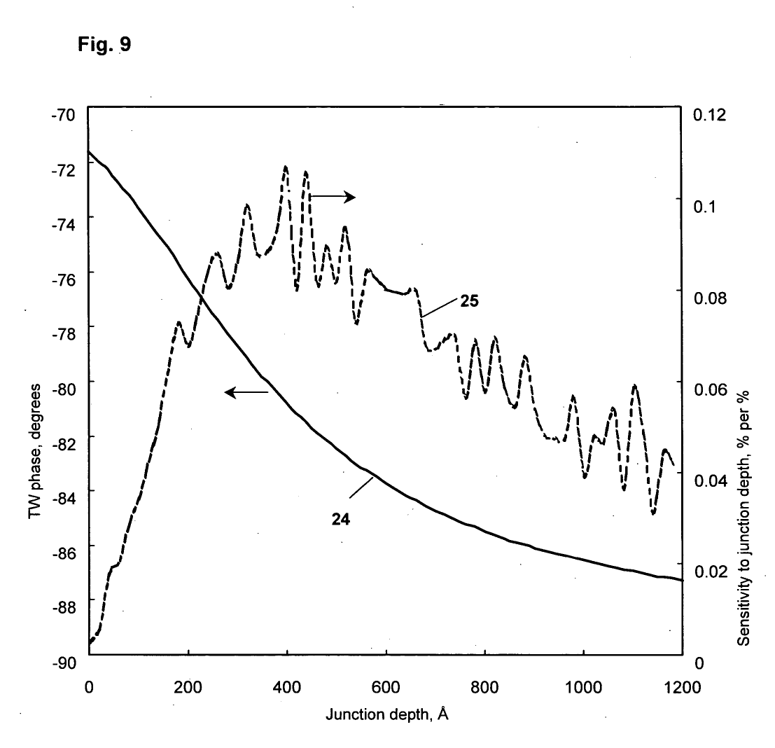

As mentioned before, despite the fact that TW signal is lower in the region of plasma-thermal interference it is still advantageous to use the probe beam wavelength corresponding to this spectral region because of the appearing phase sensitivity. This is illustrated in FIG. 9. In all probe beam wavelength spectral regions other than that of plasma-thermal interference, the TW phase remains flat (<2° change over 1000 Å of junction depth) and possesses no useful sensitivity to junction depth. At the probe beam wavelength of system 300, the TW phase 24 exhibits a strong non-oscillating dependence on junction depth (>15° change over 1000 Å of junction depth) resulting in good sensitivity 25 (right scale in FIG. 9). Therefore, in the case of system 300 both TW amplitude and phase information can be used for characterization of ultra-shallow junctions.

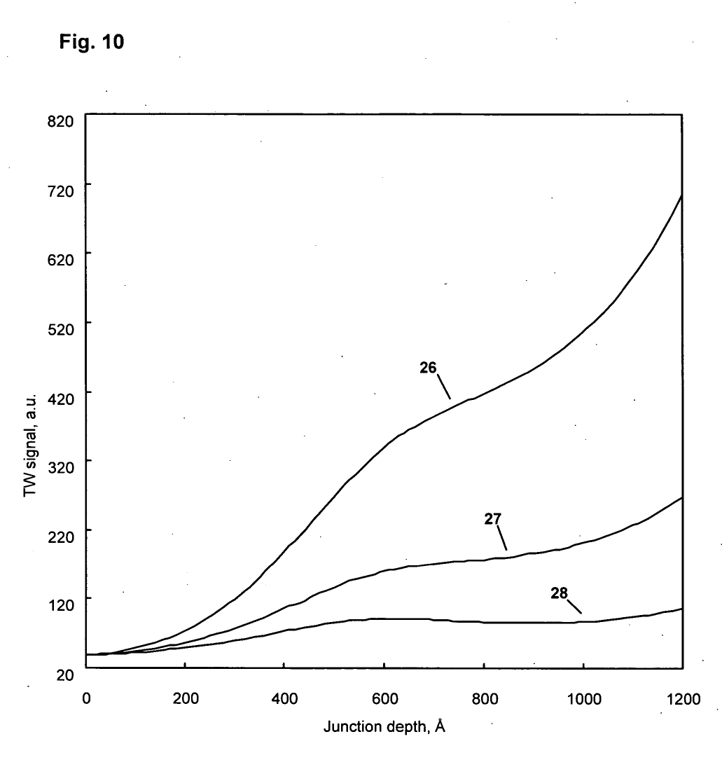

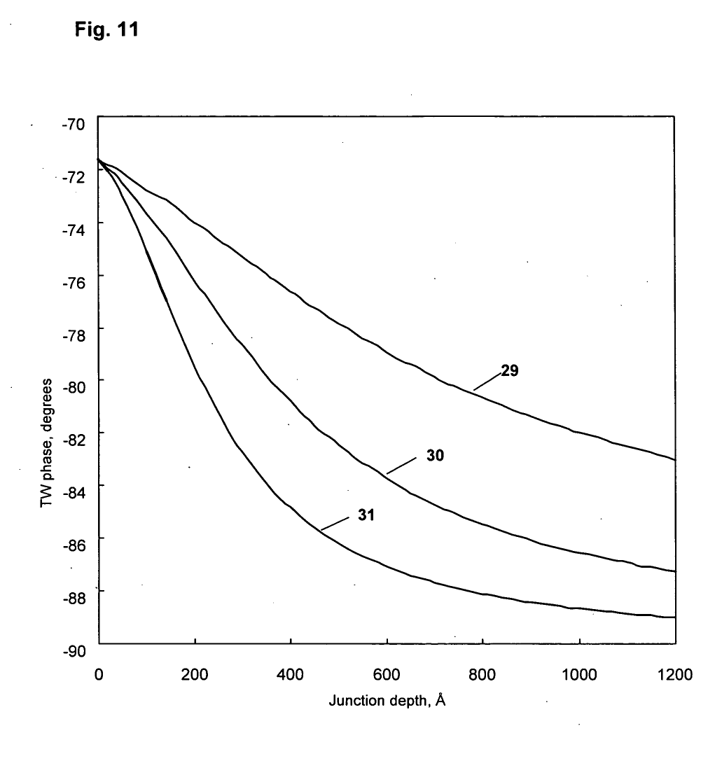

FIG. 10 and FIG. 11 refer to the method for simultaneous measurement of junction depth and carrier mobility using a new photothermal system proposed in this disclosure. TW responses 26, 27 and 28 in FIG. 10 have different ratios of carrier mobility in USJ layer (μ_{USJ}) and Si substrate (μ_{Si})−μ_{USJ}/μ_{Si}=30, 10, and 3, respectively. The corresponding TW phase responses shown in FIG. 11 are 31, 30, and 29. As can be appreciated, both TW amplitude and phase exhibit strong sensitivity to both the junction depth and μ_{USJ}. For any given USJ sample, the junction depth (Xⱼ) and carrier mobility μ_{USJ} can be easily determined from the pair of TW amplitude and phase data that defines a unique set of Xⱼ and μ_{USJ} values.

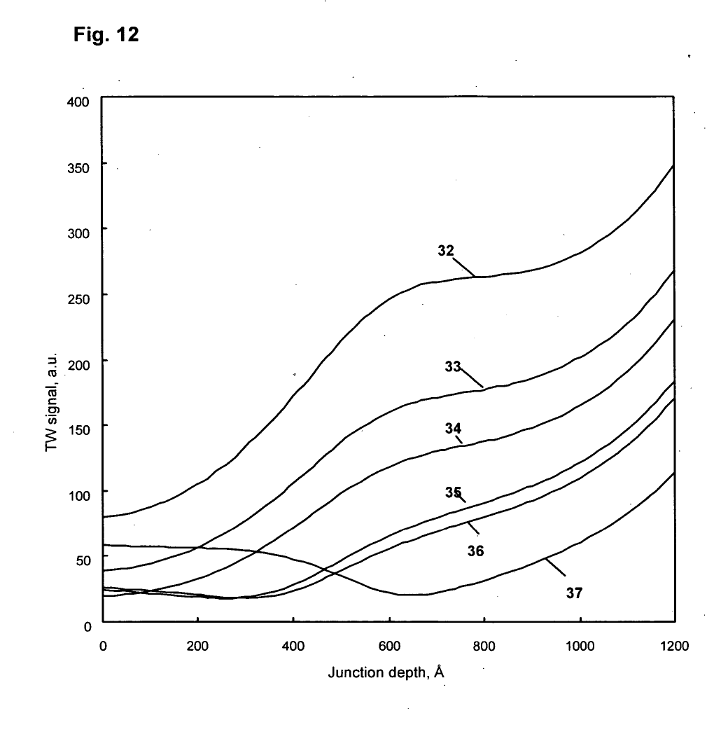

Another aspect of the present invention is to use a probe beam laser with a tunable wavelength in order to adjust probe beam to the spectral position corresponding to the maximum interference between the carrier plasma and thermal waves. Advantages of using a tunable wavelength probe beam are illustrated in FIG. 12. Tuning the probe beam wavelength from 628 nm (response 37) in steps to 675 nm (response 32) dramatically changes the TW response. TW signal sensitivity to junction depth can be varied for different USJ junction depths. Thus, by selecting the optimal wavelength the photothermal system performance could be optimized for each particular application and each particular USJ sample.

In general, it should be appreciated that the combination of components shown in FIG. 3 is representative in nature. System 300 may be implemented using a number of different configurations. In particular, this includes a number of different configurations for combining the pump and probe beams. Several of these configurations are discussed in U.S. patent application Ser. No. 2003/0234933 filed Jun. 3, 2003 (incorporated in this document by reference). It is also possible to configure system 300 to use multiple pump or multiple probe lasers. Configurations of this type are described in U.S. patent application Ser. No. 2003/0234932, filed May 16, 2003 (also incorporated in this document by reference).

All advantages of a new photothermal system of this invention could be further enhanced by combining it with the assignee's other performance improving inventions: photothermal system with multiple wavelengths, fiber optics based photothermal system, photothermal system with I-Q data analysis, etc., as well as by combination of a new photothermal system with other techniques—photothermal radiometry, 4-point probe electrical characterization methodology, etc.

TABLE I
Optical, thermal and electronic parameters used for calculations of TW
responses from USJ using new and prior art photothermal systems:

| | Prior art | New |
|---|---|---|
| Parameter | system | system |
| System parameters | | |
| Pump beam wavelength, λₚᵤₘₚ [nm] | 790 | 405 |
| Probe beam wavelength, λ_{probe} [nm] | 670 | 675 or |
| | | tunable |
| | | 600-700 |
| Modulation frequency, f [MHz] | 1.0 | 1.0 |
| Pump/probe beam diameter, a [μm] | 1.0 | 1.0 |
| Substrate parameters (crystalline Si) | | |
| Index of refraction (pump), n | 3.705 | 5.543 |
| Extinction coefficient (pump), k | 0.0029 | 0.297 |
| Index of refraction (probe), n | 3.821 | 3.808 |
| Extinction coefficient (probe), k | 0.0017 | 0.0024 |
| Temperature coefficient of n, (dn/dT)/n, ×10⁻⁶ | 125 | 126 |
| Temperature coefficient of k, (dk/dT)/k, ×10⁻⁶ | −900 | 1700 |
| Plasma coefficient of n, (dn/dN)/n, ×10⁻⁶ | −5.05 | −3.60 |
| Plasma coefficient of k, (dk/dN)/k, ×10⁻⁶ | 0 | 0 |
| Carrier diffusion coefficient, D_{Bulk} [cm/²s] | 15 | 15 |
| Carrier lifetime, τ [μs] | 10 | 10 |
| Thermal conductivity, K [W/cmK] | 1.42 | 1.42 |
| USJ parameters (doping ˜10¹⁹ cm⁻³) | | |
| Index of refraction (pump), n | 3.149 | 4.712 |
| Extinction coefficient (pump), k | 0.0029 | 0.297 |
| Index of refraction (probe), n | 3.248 | 3.237 |
| Extinction coefficient (probe), k | 0.0017 | 0.0024 |
| Temperature coefficient of n, (dn/dT)/n, ×10⁻⁶ | 148 | 148 |
| Temperature coefficient of k, (dk/dT)/k, ×10⁻⁶ | 1700 | 1600 |
| Plasma coefficient of n, (dn/dN)/n, ×10⁻⁶ | −3.55 | −3.60 |
| Plasma coefficient of k, (dk/dN)/k, ×10⁻⁶ | 0 | 0 |
| USJ carrier diffusion coefficient, D_{USJ} [cm/²s] | 1.5 | 1.5 |
| USJ carrier lifetime, τ [μs] | 0.1 | 0.1 |
| Thermal conductivity, K [W/cmK] | 1.42 | 1.42 |

What is claimed is:

1. An apparatus for evaluating a sample comprising:
a probe laser producing a probe beam;
a pump laser producing an intensity modulated pump beam having a wavelength in the near UV to UV spectrum;
optical components for directing the pump beam to excite a region of the sample and for directing the probe beam to be reflected by the excited region;
a detector for measuring the modulated changes in the probe beam induced by the interaction with the sample and generating corresponding output signals; and
a processor for evaluating the sample based on the output signals.

2. An apparatus as recited in claim 1, wherein the pump beam has a wavelength in the range of 320 to 420 nm.

3. An apparatus as recited in claim 1, wherein the pump beam has a wavelength in the range of 390 to 410 nm.

4. An apparatus as recited in claim 1, wherein the pump beam has a wavelength of 405 nm.

5. An apparatus as recited in claim 1, wherein the detector monitors changes in the modulated power of the reflected probe beam.

6. An apparatus as recited in claim 1, wherein the probe beam has a wavelength in the visible spectrum.

7. An apparatus as recited in claim 1, wherein the probe beam wavelength is tunable.

8. An apparatus as recited in claim 1, wherein the processor evaluates a characteristic of a shallow junction in the sample.

9. An apparatus as recited in claim 8, wherein the characteristic is one of the following: junction depth, carrier mobility, carrier concentration, profile abruptness and carrier lifetime.

10. An apparatus as recited in claim 1, wherein the processor characterizes ion implantation in the sample.

11. An apparatus as recited in claim 1, that further comprises:
a beam combiner configured to join the pump and probe beams into a collinear beam; and
optical fibers for transporting the probe and pump beams from their respective sources to the beam combiner.

12. A method for evaluating a sample comprising:
generating a probe beam;
generating an intensity modulated pump beam having a wavelength in the near UV to UV spectrum;
directing the pump beam to excite a region of the sample;
directing the probe beam to be reflected by the excited region;
measuring the modulated changes in the probe beam induced by the interaction with the sample and generating corresponding output signals; and
evaluating the sample based on the output signals.

13. A method as recited in claim 12, wherein the pump beam has a wavelength in the range of 320 to 420 nm.

14. A method as recited in claim 12, wherein the pump beam has a wavelength in the range of 390 to 410 nm.

15. A method as recited in claim 12, wherein the pump beam has a wavelength of 405 nm.

16. A method as recited in claim 12, wherein the probe beam has a wavelength in the visible spectrum.

17. A method as recited in claim 12, wherein the probe beam wavelength is tunable.

18. A method as recited in claim 12, that further comprises evaluating a characteristic of a shallow junction in the sample.

19. A method as recited in claim 18, wherein the characteristic is one of the following: junction depth, carrier mobility, carrier concentration, profile abruptness and carrier lifetime.

20. A method as recited in claim 12, that further comprises characterizing ion implantation in the sample.

21. An apparatus for evaluating a sample comprising:
an intensity modulated pump laser beam having a wavelength in the UV spectrum directed to the sample to periodically excite a region thereof;
a probe laser beam directed within the periodically excited region on the sample and reflect therefrom;
a detector for measuring the modulated changes in the probe laser beam induced by the interaction with the sample and generating output signals in response thereto; and
a processor for evaluating the sample based on the output signals.

22. An apparatus as recited in claim 21, wherein the pump beam has a wavelength in the range of 320 to 420 nm.

23. An apparatus as recited in claim 21, wherein the pump beam has a wavelength in the range of 390 to 410 nm.

24. An apparatus as recited in claim 21, wherein the pump beam has a wavelength of 405 nm.

25. An apparatus as recited in claim 21, wherein the detector monitors changes in the modulated power of the reflected probe beam.

26. An apparatus as recited in claim 21, wherein the probe beam has a wavelength in the visible spectrum.

27. An apparatus as recited in claim 24, wherein the probe beam wavelength is tunable.

28. An apparatus as recited in claim 21, wherein the processor evaluates the depth of a shallow junction in a semiconductor sample.
